(19) United States
(12) Patent Application Publication
(10) Pub. No.: US 2006/0028797 A1
(43) Pub. Date: Feb. 9, 2006

(54) Computer facility having fan control device

(76) Inventor: Ching Lin Chou, Taichung (TW)

Correspondence Address: Ching Lin Chou, P.O. Box 63-99, Taichung, 406, TW

(21) Appl. No.: 10/911,354

(22) Filed: Aug. 5, 2004

(51) Int. Cl. H05K 7/20

(52) U.S. Cl. 361/695; 165/80.3

(57) ABSTRACT

A computer facility includes a housing having one or more fan devices for air circulating and heat dissipating purposes, a power supply device disposed in the housing and having one or more fan devices for air circulating and heat dissipating purposes, and a control device attached to the power supply device to operate the fan devices for a predetermined time period after the power supply device is switched off. The control device selectively operates the fan device at a predetermined temperature or at a predetermined idling speed after the power supply device is switched off.

### BACKGROUND OF THE INVENTION

1. Field of the Invention

The present invention relates to a computer facility, and more particularly to a computer facility having a control device to control fan devices.

2. Description of the Prior Art

Typical computer facilities may comprise one or more fan devices attached thereto, for air circulating purposes, and for heat dissipating purposes, and for preventing the electric parts or elements of the computer facilities from being damaged by over-heating.

Normally, the fan devices are opened or switched on when the computer facilities are operated or switched on, and will be switched off when the computer facilities are not operated or are switched off.

However, when the computer facilities are not operated or are switched off, a great heat may remain within the computer facilities and may not be suitably dissipated from the computer facilities after the fan devices are switched off, such that the electric parts or elements of the computer facilities may also be heated and damaged by the heat remained in the computer facilities after the computer facilities have been switched off, or after the computer facilities are not operated.

The present invention has arisen to mitigate and/or obviate the afore-described disadvantages of the conventional computer facilities.

### SUMMARY OF THE INVENTION

The primary objective of the present invention is to provide a computer facility including a control device to control and to operate fan devices either within a predetermined or set time period, or under a constant working temperature, or with idling.

In accordance with one aspect of the invention, there is provided a computer facility comprising a housing including at least one first fan device attached thereto, for air circulating and heat dissipating purposes, a power supply device disposed in the housing, and including at least one second fan device attached thereto, for air circulating and heat dissipating purposes, and a control device attached to the power supply device, to operate the first fan device and the second fan device for a predetermined time period after the power supply device is switched off.

The control device selectively operates the first fan device and the second fan device at a predetermined temperature after the power supply device is switched off.

The control device selectively operates the first fan device and the second fan device at a predetermined idling speed after the power supply device is switched off.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a perspective view of a computer facility in accordance with the present invention;

FIG. 2 is a perspective view of a power supply device for the computer facility; and

FIG. 3 is a block diagram illustrating the operation of the control device for the computer facility.

### DETAILED DESCRIPTION OF THE PREFERRED EMBODIMENT

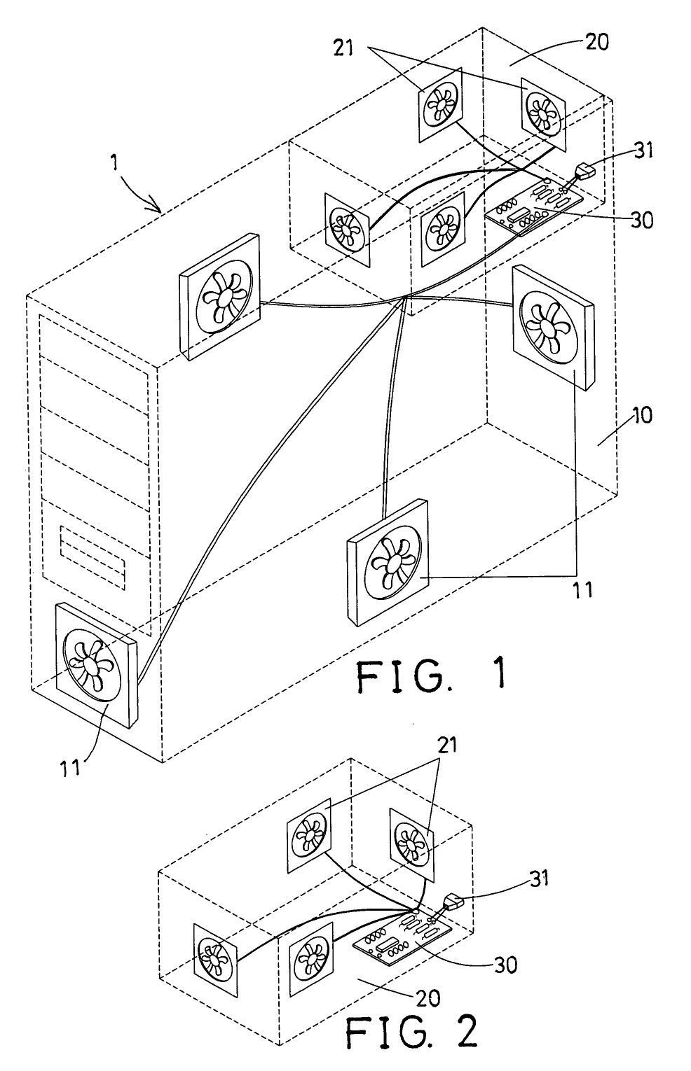

Referring to the drawings, and initially to FIG. 1, a computer facility 1 in accordance with the present invention comprises a housing 10 including one or more fan devices 11 attached thereto, for air circulating purposes, and for heat dissipating purposes, and for preventing the electric parts or elements (not shown) of the computer facility 1 from being damaged by over-heating.

The computer facility 1 further includes a power supply device 20 (FIG. 2) disposed or received in the housing 10 (FIG. 1), and the power supply device 20 also includes one or more fan devices 11 attached thereto, for air circulating purposes, and for heat dissipating purposes, and for preventing the power supply device 20 from being damaged by over-heating.

The power supply device 20 further includes a control device 30 attached thereto or received therein, and having a plug or coupler 31 for coupling to electric power sources or the like. The control device 30 is provided to control the fan devices 11 and/or 21 of the computer facility 1 and/or the power supply device 20.

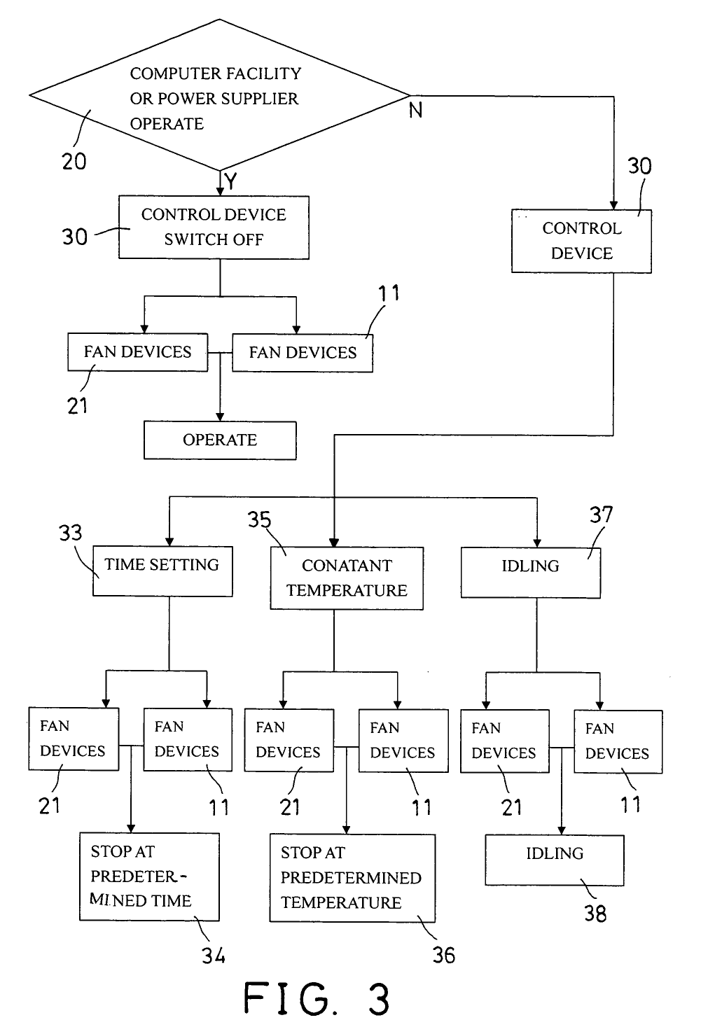

For example, as shown in FIG. 3, when the computer facility 1 and/or the power supply device 20 is operated or energized, the control device 30 may be switched off, and the fan devices 11 and 21 of the computer facility 1 and the power supply device 20 may be continuously operated to circulate air or to dissipate heat from the computer facility 1 and the power supply device 20.

When the computer facility 1 and/or the power supply device 20 is not operated or not energized or switched off, the control device 30 may be switched on or operated in order to control the fan devices 11 and 21 of the computer facility 1 and the power supply device 20 in different operating modes 33, 35, 37.

For example, in the time setting operating mode 33, the control device 30 may operate or control the fan devices 11 and 21 of the computer facility 1 and the power supply device 20 to operate in a predetermined or set time period, and to continuously operate the fan devices 11 and 21 to circulate air or to dissipate heat from the computer facility 1 and the power supply device 20 after the computer facility 1 and/or the power supply device 20 is not operated or not energized or switched off, and to stop the fan devices 11 and 21 after the predetermined or set time period is achieved, at process 34.

Alternatively, in the constant temperature operating mode 35, the control device 30 may operate or control the fan devices 11 and 21 of the computer facility 1 and the power supply device 20 to operate at a predetermined or constant temperature, and to continuously operate the fan devices 11 and 21 to circulate air or to dissipate heat from the computer facility 1 and the power supply device 20 when the computer facility 1 and/or the power supply device 20 still has a high or predetermined temperature, and to stop the fan devices 11 and 21 after the computer facility 1 and/or the power supply device 20 has lowered than the predetermined or constant temperature, at process 36.

Further alternatively, in the idling operating mode 37, the control device 30 may operate or control the fan devices 11 and 21 of the computer facility 1 and the power supply device 20 to operate at a predetermined or constant idling speed, at process 38, and to continuously operate the fan devices 11 and 21 to circulate air or to dissipate heat from the computer facility 1 and the power supply device 20 after the computer facility 1 and/or the power supply device 20 is not operated or not energized or switched off, and to wait until the computer facility 1 and/or the power supply device 20 is switched on or operated or energized again.

Accordingly, the computer facility in accordance with the present invention includes a control device to control and to operate fan devices either within a predetermined or set time period, or under a constant working temperature, or with idling.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A computer facility comprising:
a housing including at least one first fan device attached thereto, for air circulating and heat dissipating purposes,
a power supply device disposed in said housing, and including at least one second fan device attached thereto, for air circulating and heat dissipating purposes, and
a control device attached to said power supply device, to operate said at least one first fan device and said at least one second fan device for a predetermined time period after said power supply device is switched off.

2. The computer facility as claimed in claim 1, wherein said control device selectively operates said at least one first fan device and said at least one second fan device at a predetermined temperature after said power supply device is switched off.

3. The computer facility as claimed in claim 1, wherein said control device selectively operates said at least one first fan device and said at least one second fan device at a predetermined idling speed after said power supply device is switched off.

4. A computer facility comprising:
a housing including at least one first fan device attached thereto, for air circulating and heat dissipating purposes,
a power supply device disposed in said housing, and including at least one second fan device attached thereto, for air circulating and heat dissipating purposes, and
a control device attached to said power supply device, to operate said at least one first fan device and said at least one second fan device at a predetermined temperature after said power supply device is switched off.

5. The computer facility as claimed in claim 4, wherein said control device selectively operates said at least one first fan device and said at least one second fan device for a predetermined time period after said power supply device is switched off.

6. The computer facility as claimed in claim 4, wherein said control device selectively operates said at least one first fan device and said at least one second fan device at a predetermined idling speed after said power supply device is switched off.

7. A computer facility comprising:
a housing including at least one first fan device attached thereto, for air circulating and heat dissipating purposes,
a power supply device disposed in said housing, and including at least one second fan device attached thereto, for air circulating and heat dissipating purposes, and
a control device attached to said power supply device, to operate said at least one first fan device and said at least one second fan device at a predetermined idling speed after said power supply device is switched off.

8. The computer facility as claimed in claim 7, wherein said control device selectively operates said at least one first fan device and said at least one second fan device for a predetermined time period after said power supply device is switched off.

9. The computer facility as claimed in claim 7, wherein said control device operates said at least one first fan device and said at least one second fan device at a predetermined temperature.
